(19) United States
(12) Patent Application Publication
(10) Pub. No.: US 2026/0293578 A1
(43) Pub. Date: Sep. 24, 2026

(54) SEPARATION APPARATUS, SEPARATION SYSTEM, AND SEPARATION METHOD

(71) Applicant: Tokyo Electron Limited, Tokyo (JP)

(72) Inventors: Masaru HONDA, Koshi City, Kumamoto (JP); Takashi SAKAUE, Kikuchi-gun, Kumamoto (JP)

(73) Assignee: Tokyo Electron Limited, Tokyo (JP)

(21) Appl. No.: 19/478,281

(22) PCT Filed: Apr. 15, 2024
(86) PCT No.: PCT/JP2024/014938

§ 371 Date: Oct. 24, 2025

(30) Foreign Application Priority Data
Apr. 27, 2023 (JP) 2023-073628

(51) Int. Cl. H10P 72/00; H10P 72/70

(52) U.S. Cl. CPC H10P 72/0428; H10P 72/744

(57) ABSTRACT

A separation apparatus is configured to separate a combined substrate, in which a first substrate and a second substrate are bonded, into the first substrate and the second substrate. The separation apparatus includes a first holder configured to hold the first substrate of the combined substrate; a second holder configured to hold the second substrate of the combined substrate; a separation guide configured to be advanced between the first substrate and the second substrate of the combined substrate to form a separation start portion where separation begins; and a gas ejector configured to eject a gas between the first substrate and the second substrate of the combined substrate. The gas ejector changes at least one of an ejection position, an ejection direction, or an ejection amount as an ejection state of the gas after the separation start portion is formed by the separation guide and the gas is ejected.

### TECHNICAL FIELD

The various aspects and embodiments described herein pertain generally to a separation apparatus, a separation system, and a separation method.

### BACKGROUND

Patent Document 1 discloses a separation apparatus for separating two sheets of substrates (a processing target substrate and a support substrate) that form together a combined substrate. In this separation apparatus, while holding the processing target substrate with a first holder at a lower side and the support substrate with a second holder at an upper side, a blade is inserted between the processing target substrate and the support substrate to trigger separation therebetween. The second holder attracts the support substrate by moving downwards a plurality of movable attraction members, each having an attraction pad, and then gradually lifts the support substrate starting from the movable attraction members on the entry side of the blade, thereby separating the support substrate from the processing substrate from the blade side.

### PRIOR ART DOCUMENT

Patent Document 1: Japanese Patent Laid-open Publication No. 2015-207776

### DISCLOSURE OF THE INVENTION

### Problems to be Solved by the Invention

Exemplary embodiments provide a technique capable of efficiently and stably separating two sheets of substrates.

### Means for Solving the Problems

In an exemplary embodiment, a separation apparatus configured to separate a combined substrate, in which a first substrate and a second substrate are bonded, into the first substrate and the second substrate includes a first holder configured to hold the first substrate of the combined substrate; a second holder configured to hold the second substrate of the combined substrate; a separation guide configured to be advanced between the first substrate and the second substrate of the combined substrate to form a separation start portion where separation begins; and a gas ejector configured to eject a gas between the first substrate and the second substrate of the combined substrate. The gas ejector changes at least one of an ejection position, an ejection direction, or an ejection amount as an ejection state of the gas after the separation start portion is formed by the separation guide and the gas is ejected.

### Effect of the Invention

According to the exemplary embodiments, it is possible to efficiently and stably separate two sheets of substrates.

### BRIEF DESCRIPTION OF THE DRAWINGS

FIG. 1 is a plan view schematically illustrating a separation system.

FIG. 2 is a side view schematically illustrating a configuration of a delivery station of the separation system.

FIG. 3 is a cross sectional view schematically illustrating a combined substrate to be separated.

FIG. 4 is a side view schematically illustrating a configuration of a separation apparatus according to a first exemplary embodiment.

FIG. 5 is a plan view illustrating a support member and an upper attraction device of a first holder.

FIG. 6 is a flowchart illustrating a separation method of the separation apparatus.

FIG. 7A to FIG. 7C are first to third explanatory diagrams illustrating operations in the separation method.

FIG. 8A is an explanatory diagram providing an enlarged view of a reciprocating motion of a nozzle, FIG. 8B is an explanatory diagram providing an enlarged view of an ejection state of air being introduced between an upper wafer and a lower wafer, and FIG. 8C is an explanatory diagram illustrating a separation state between the upper wafer and the lower wafer caused by the ejection of the air.

FIG. 9A is a timing chart illustrating the separation method according to the first exemplary embodiment, and FIG. 9B is a timing chart illustrating the separation method of the separation apparatus according to a first modification example.

FIG. 10 is a plan view illustrating a gas ejector of a separation apparatus according to a second exemplary embodiment.

FIG. 11A to FIG. 11C are first to third explanatory diagrams illustrating an operation of the gas ejector according to the second exemplary embodiment.

FIG. 12 is a plan view illustrating a gas ejector of a separation apparatus according to a third exemplary embodiment.

FIG. 13A to FIG. 13C are first to third explanatory diagrams illustrating an operation of the gas ejector according to the third exemplary embodiment.

### DETAILED DESCRIPTION

Hereinafter, exemplary embodiments of the present disclosure will be explained with reference to the accompanying drawings. In the various drawings, same parts will be assigned same reference numerals, and redundant descriptions thereof will be omitted.

Hereinafter, exemplary embodiments of the present disclosure will be explained with reference to the accompanying drawings. In the various drawings, same parts will be assigned same reference numerals, and redundant descriptions thereof will be omitted. In the following description, the X-axis, Y-axis, and Z-axis directions are mutually orthogonal directions. The X-axis and Y-axis directions are horizontal directions, and the Z-axis direction is a vertical direction.

### Configuration of Separation System 100

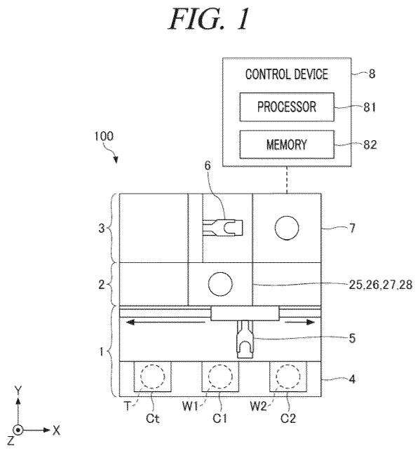

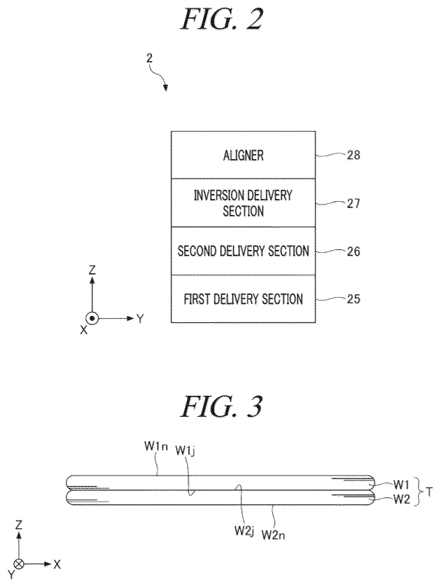

First, a configuration of a separation system 100 according to an exemplary embodiment of the present disclosure will be explained with reference to FIG. 1 to FIG. 3. As depicted in FIG. 1 and FIG. 2, the separation system 100 includes a separation apparatus 7 that separates a combined substrate T, in which a first substrate W1 and a second substrate W2 are bonded, into the first substrate W1 and the second substrate W2. The separation system 100 is configured as a system in which the combined substrate T is carried into the separation apparatus 7 by a second transfer device 6 to be described later to be separated by the separation apparatus 7, and the separated first and second substrates W1 and W2 are carried out from the separation apparatus 7.

The first substrate W1 and second substrate W2 that constitute the combined substrate T are formed as circular plates of approximately the same shape (same diameter). Hereinafter, as shown in FIG. 3, the first substrate W1, which is one of the substrates, may be referred to as “upper wafer W1,” the second substrate W2, which is the other of the substrates, may be referred to as “lower wafer W2,” and the combined substrate T may be referred to as “combined wafer T.” Also, in the following description, among plate surfaces of the upper wafer W1, the plate surface to be bonded to the lower wafer W2 will be referred to as “bonding surface W1j,” and the plate surface opposite the bonding surface W1j will be referred to as “non-bonding surface W1n.” Likewise, among plate surfaces of the lower wafer W2, the plate surface to be bonded to the upper wafer W1 will be referred to as “bonding surface W2j,” and the plate surface opposite the bonding surface W2j will be referred to as “non-bonding surface W2n.” The combined wafer T, the upper wafer W1, and the lower wafer W2 are not limited to having circular shapes but may have other shapes, such as polygonal shapes.

At least one of the upper wafer W1 and the lower wafer W2 is a semiconductor substrate, such as a silicon wafer or a compound semiconductor wafer, on which multiple electronic circuits are formed. One of the upper wafer W1 and the lower wafer W2 may be a bare wafer without electronic circuits formed thereon. Although not particularly limited, the compound semiconductor wafer may be, by way of example, a GaAs wafer, a SiC wafer, a GaN wafer, or an InP wafer.

The upper wafer W1 and the lower wafer W2 may be chemically bonded, for example. By way of example, the surfaces (bonding surfaces W1j and W2j) of the upper and lower wafers W1 and W2 are modified by plasma processing, and the modified surfaces are hydrophilized by pure water and bonded to each other by a van der Waals force and a hydrogen bond (intermolecular force). Alternatively, the upper wafer W1 and the lower wafer W2 may be bonded by an appropriate adhesive.

As depicted in FIG. 1, the separation system 100 includes a carry-in/out station 1, a delivery station 2, and a processing station 3. The carry-in/out station 1, the delivery station 2, and the processing station 3 are respectively configured as separable units, and are arranged in this order in the positive Y-axis direction.

The carry-in/out station 1 performs a carry-in of the combined wafer T, a carry-out of the separated upper and lower wafers W1 and W2, and the like. The carry-in/out station 1 includes a placement section 4 and a first transfer device 5.

The placement section 4 has a plurality of cassette placement tables (three in FIG. 1) each for placing thereon a cassette such as a front-opening unified pod (FOUP) capable of accommodating a multiple number of substrates. The cassettes placed on the respective cassette placement tables include a cassette Ct accommodating the combined wafer T, a cassette C1 capable of accommodating the separated upper wafer W1, and a cassette C2 capable of accommodating the separated lower wafer W2.

The first transfer device 5 is located adjacent to the positive Y-axis side of the placement section 4, and serves to transfer the combined wafer T, the upper wafer W1, and the lower wafer W2. The first transfer device 5 includes, for example, a base and multiple transfer arms each configured to be pivotable around a vertical axis of the base, and moves the substrate, which is held thereby, in horizontal and vertical directions. The first transfer device 5 is an example of a substrate transfer device.

In the carry-in/out station 1, the first transfer device 5 transfers the combined wafer T from the cassette Ct to the delivery station 2, and also transfers the separated upper and lower wafers W1 and W2 from the delivery station 2 to the cassettes C1 and C2, respectively.

The delivery station 2 delivers the combined wafer T, the separated upper wafer W1, and the separated lower wafer W2. For example, as shown in FIG. 2, the delivery station 2 includes a first delivery section 25, a second delivery section 26, an inversion delivery section 27, and an aligner 28. The first delivery section 25, the second delivery section 26, the inversion delivery section 27, and the aligner 28 are arranged in this order in a vertically upward direction (positive Z-axis direction).

The combined wafer T transferred from the carry-in/out station 1 is placed in the first delivery section 25. The combined wafer T placed in the first delivery section 25 is transferred to the processing station 3 by the second transfer device 6 to be described later.

The separated lower wafer W2 is placed in the second delivery section 26. The separated lower wafer W2 placed in the second delivery section 26 is transferred to the carry-in/out station 1 by the first transfer device 5.

The separated upper wafer W1 is placed in the inversion delivery section 27. The inversion delivery section 27 is provided with an inverting mechanism (not shown) configured to invert top and bottom surfaces of the separated upper wafer W1 upside down. After its top and bottom surfaces are inverted by the inverting mechanism in the inversion delivery section 27, the separated upper wafer W1 is transferred to the carry-in/out station 1 by the first transfer device 5.

The aligner 28 performs an alignment processing on some or all of the combined wafer T, the separated upper wafer W1, and the separated lower wafer W2. For example, when aligning the combined wafer T, the aligner 28 holds and rotates the combined wafer T, detects a position of a notch of the combined wafer T being rotated, and calculates an eccentric amount of the combined wafer T. The separation system 100 appropriately operates the aligner 28 and the first transfer device 5 or the second transfer device 6 based on this eccentric amount, thereby adjusting a direction of the combined wafer T in the horizontal direction. The same applies when aligning the upper wafer W1 or the lower wafer W2.

The processing station 3 is equipped with the second transfer device 6 and the separation apparatus 7, and performs a separation processing of the combined wafer T. In this processing station 3, the second transfer device 6 and the separation apparatus 7 are arranged in the X-axis direction, for example.

The second transfer device 6 transfers the combined wafer T and the separated upper and lower wafers W1 and W2 between the delivery station 2 and the separation apparatus 7. The second transfer device 6 includes, by way of example, a base and multiple transfer arms each configured to be pivotable around a vertical axis of the base, and serves to move the held substrate horizontally and vertically. The second transfer device 6 is an example of the substrate transfer device.

The processing station 3 performs a carry-in processing of carrying the combined wafer T from the delivery station 2 into the separation apparatus 7 by using the second transfer device 6. The processing station 3 also performs, by using the second transfer device 6, a carry-out processing of carrying out the separated lower wafer W2 from the separation apparatus 7 to the delivery station 2 and a carrying-out processing of carrying out the separated upper wafer W1 from the separation apparatus 7 to the delivery station 2 separately.

The separation apparatus 7 performs a separation processing of separating the combined wafer T carried in by the second transfer device 6 into the upper wafer W1 and the lower wafer W2. A specific configuration and operation of this separation apparatus 7 will be described in detail later.

The separation system 100 also includes a control device 8 that controls the operation of the separation system 100. The control device 8 is a computer equipped with one or more processors 81, a memory 82, and a non-illustrated input/output interface. The one or more processors 81 are implemented by one of a central processing unit (CPU), a graphics processing unit (GPU), an application-specific integrated circuit (ASIC), a field-programmable gate array (FPGA), and a circuit composed of a plurality of discrete semiconductors, or a combination thereof. The memory 92 includes a non-volatile memory and a volatile memory. The memory 82 stores a program for controlling various types of processes, and the processor 81 controls the operation of the separation system 100 by reading and executing the program stored in the memory 82.

In controlling the separation system 100, the control device 8 first takes out the combined wafer T from the cassette Ct in the placement section 4 by the first transfer device 5 of the carry-in/out station 1, and places the taken combined wafer T in the first delivery section 25 of the delivery station 2. Subsequently, the control device 8 takes out the combined wafer T from the first delivery section 25 by the second transfer device 6 of the processing station 3, and carries it into the aligner 28. The control device 8 calculates the eccentric amount of the combined wafer T by the aligner 28, and adjusts, based on this eccentric amount, a receiving position (a direction in the horizontal direction) of the combined wafer T by the second transfer device 6. Also, the control device 8 transfers the combined wafer T from the aligner 28 to the separation apparatus 7 by the second transfer device 6.

Then, the separation apparatus 7 performs a separation processing under the control of the control device 8, and separates the combined wafer T into the upper wafer W1 and the lower wafer W2.

After the separation by the separation apparatus 7, the control device 8 operates the second transfer device 6 to carry out the lower wafer W2 from the separation apparatus 7 to the aligner 28, where a direction of the lower wafer W in the horizontal direction is adjusted. Then, the lower wafer W is transferred to the second delivery section 26. The control device 8 then controls the first transfer device 5 to take out the lower wafer W2 from the second delivery section 26 and store it in the cassette C2 in the carry-in/out station 1. Once a certain number of lower wafers W2 are accommodated in the cassette C2, the cassette C2 is taken out from the carry-in/out station 1.

Furthermore, at a timing different from that of the transfer of the lower wafer W2, the control device 8 operates the second transfer device 6 to transfer the upper wafer W1 from the separation apparatus 7 to the aligner 28, where a direction of the upper wafer W1 in the horizontal direction is adjusted. Then, the upper wafer W1 is transferred to the inversion delivery section 27. Further, the control device 8 turns the top and bottom surfaces of the upper wafer W1 with the inverting mechanism of the inversion deliver section 27. As a result, the upper wafer W1 is put into a state where its bonding surface W1j faces upwards. The control device 8 controls the first transfer device 5 to take out the upper wafer W1 from the inversion delivery section 27 and store it in the cassette C1 in the carry-in/out station 1. Once a certain number of upper wafers W1 are accommodated in the cassette C1, the cassette C1 is taken out from the carry-in/out station 1.

### First Exemplary Embodiment

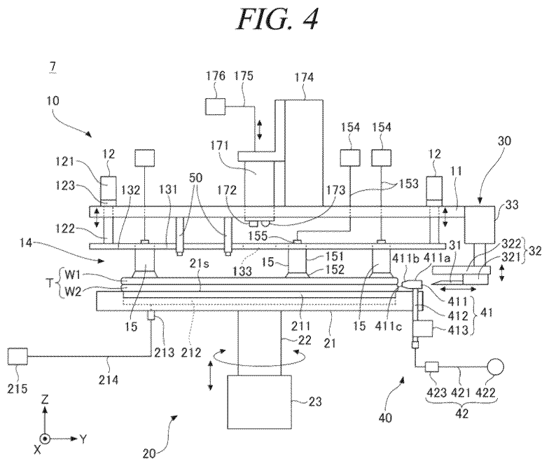

Now, a configuration of the separation apparatus 7 according to a first exemplary embodiment will be explained with reference to FIG. 4. The separation apparatus 7 holds the combined wafer T interposed along a vertical direction (Z-axis direction), and separates the upper wafer W1 and the lower wafer W2 of the combined wafer T. To this end, the separation apparatus 7 has a processing vessel 7c (see FIG. 1) into which the combined wafer T is carried, and a first holder 10, a second holder 20, and a separation guide 30 are provided inside the processing vessel 7c. The separation guide 30 forms a separation start portion that triggers the separation of the upper wafer W1 and the lower wafer W2 of the combined wafer T. The operation of each component of the separation apparatus 7 is controlled by the control device 8 shown in FIG. 1. Here, the separation apparatus 7 may be equipped with a control computer (a control board, etc.) for receiving an instruction from the control device 8, and may be controlled by the control computer.

The first holder 10 holds the upper wafer W1 of the combined wafer T by attracting the non-bonding surface W1n of the upper wafer W1. The first holder 10 includes a base member 11, a pair of (two) elevating mechanisms 12 provided at the base member 11, a support member 13 supported by the pair of elevating mechanisms 12, and an upper attraction device 14 supported by the support member 13 and configured to apply an attracting pressure to the upper wafer W1.

The base member 11 is a plate member of an appropriate thickness, and is fixed directly or indirectly to, for example, a side wall or a ceiling wall of the processing vessel 7c (see FIG. 1). The base member 11 has a rigidity that does not allow elastic deformation, and extends horizontally in the processing vessel 7c.

The pair of elevating mechanisms 12 are fixed to the top of the base member 11, and are positioned at the same height. The elevating mechanisms 12 fixed to the base member 11 move the support member 13, which is positioned vertically below the base member 11, up and down. Each elevating mechanism 12 includes a main body 121, a shaft 122 protruding vertically downwards from the main body 121, and a load cell 123 configured to detect a load on the shaft 122.

The main body 121 is mounted to the base member 11, and a driving source configured to move the shaft 122 vertically and a transmission mechanism (both are not shown) are provided inside the main body 121. The main body 121 is connected to the control device 8, and raises and lowers the shaft 122 under the control of the control device 8. The control device 8 is capable of moving the shafts 122 of the pair of elevating mechanisms 12 independently.

The shaft 122 extends linearly in the vertical direction, and supports the support member 13 connected to its lower end. The load cell 123 detects the load applied on the shaft 122, and transmits the detection result to the control device 8. The control device 8 controls the height position of the support member 13 based on the detection result of the load cell 123.

The support member 13 is a thin plate-shaped member that supports the upper attraction device 14 configured to attract the upper wafer W1. The support member 13 is made of, for example, a metal material, and is configured to be elastically deformable. The support member 13 is suspended to bridge the pair of elevating mechanisms 12, facing the second holder 20. With this configuration, a bottom surface of the support member 13 faces the combined wafer T when the combined wafer T is held on the second holder 20.

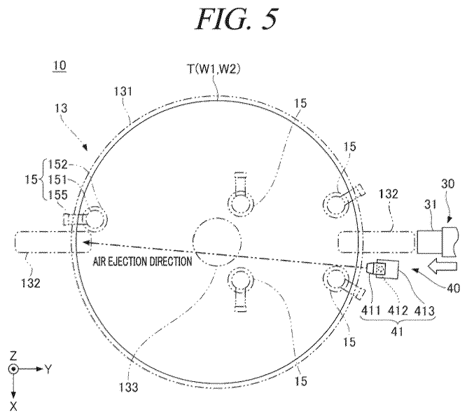

As shown in FIG. 5, the support member 13 has a circular plate 131, and a pair of protruding plate 132 provided at two opposite sides of the circular plate 131 in the Y-axis direction. The circular plate 131 and the pair of protruding plates 132 are firmly secured to each other by an appropriate connection member, such as screw fastening, welding, or adhesion. The circular plate 131 and the pair of protruding plates 132 may be molded as a single structure. Further, in FIG. 5, the configuration vertically above the combined wafer T is indicated by an imaginary line (dashed double-dotted line).

The circular plate 131 is formed in a shape of a perfect circle with a diameter approximately equal to that of the upper wafer W1. The center of the circular plate 131 is approximately aligned with the center of an attraction surface 21s of the second holder 20. The circular plate 131 faces the upper wafer W1 when the combined wafer T is held on the second holder 20. This circular plate 131 directly supports the upper attraction device 14.

A through hole 133 is formed in a thickness direction through a central region of the circular plate 131 including the center thereof. The through hole 133 allows a delivery holder 17 to be described later (see FIG. 4) to pass therethrough, thereby enabling the delivery holder 17 to hold the upper wafer W1.

Further, the circular plate 131 may also have multiple small holes (not shown) formed therethrough in the thickness direction to facilitate elastic deformation of the circular plate 131. Furthermore, the circular plate 131 may have multiple ribs or grooves extending in the X-axis direction along the Y-axis direction, thereby suppressing elastic deformation of the circular plate 131 in the X-axis direction while promoting elastic deformation in the Y-axis direction.

The pair of protruding plates 132 protrude in opposite directions from an outer periphery of the circular plate 131 in the Y-axis direction. A protruding end of each protruding plate 132 is connected to the shaft 122 of the corresponding elevating mechanism 12. With this configuration, the protruding plates 132 are respectively raised and lowered vertically (in the Z-axis direction) by the pair of elevating mechanisms 12, and the circular plate 131 can change its posture in the horizontal direction depending on the height positions of the protruding plates 132 (shafts 122 of the elevating mechanisms 12). Furthermore, the support member 13 is elastically deformed to bend in the Y-axis direction, thereby supporting the upper attraction device 14 elastically.

As illustrated in FIG. 4 and FIG. 5, the upper attraction device 14 supported by the support member 13 includes multiple attraction members 15. Each attraction member 15 includes a vertically extending cylindrical body 151, a contact body 152 provided at a lower end of the cylindrical body 151, and a suction path 153 connected to the cylindrical body 151. The suction path 153 of each attraction member 15 is provided with an attraction device 154 such as a vacuum pump. Alternatively, the respective suction paths 153 may converge externally and be connected to a single attraction device 154.

The cylindrical body 151 has therein a suction space extending along an axial direction thereof. The cylindrical body 151 is firmly connected to the circular plate 131 of the support member 13, and protrudes on the bottom surface of the support member 13 (the surface facing the upper wafer W1). When the support member 13 is horizontal, the contact bodies 152 of the respective cylindrical bodies 151 are positioned at the same height. Furthermore, a port 155 connected to the suction path 153 is provided in the cylindrical body 151 on the top surface side of the support member 13.

The contact body 152 is formed to have, for example, a truncated cone shape or a cylindrical shape, and constitutes a member that directly comes into contact with the non-bonding surface W1n of the upper wafer W1. This contact body 152 is desirably formed of a rubber material or other resin material, and more desirably, a material with high rigidity (difficult to elastically deform). If the contact body 152 is largely deformed when the first holder 10 is raised, the attracted portion of the upper wafer W1 would also be deformed significantly, raising a risk that the upper wafer W1 or the lower wafer W2 may be damaged. By way of example, a flat pad with a space height of 0.5 mm or less may be used as the contact body 152.

Each attraction member 15 applies an attracting pressure to the contact body 152 from the attraction device 154 via the suction path 153 and the cylindrical body 151 with the contact body 152 in contact with the non-bonding surface W1n of the upper wafer W1, thereby attracting the upper wafer W1.

A total of five attraction members 15 are provided at the support member 13. One pair (two) of the attraction members 15 are disposed on the positive Y-axis side of the support member 13. This pair of attraction members 15 on the negative Y-axis side are fixed so as to be arranged in the X-axis direction with the protruding plate 132 therebetween. These attraction members 15 on the positive Y-axis side hold the upper wafer W1 at a position overlapping (or near) the separation start portion formed by the aforementioned separation guide 30 during the separation processing.

Another pair (two) of the attraction members 15 are provided on the through hole 133 side of the support member 13 (on the more positive Y-axis side than the center of the support member 13). This pair of attraction members 15 on the central side are fixed so as to be arranged in the X-axis direction with the through hole 133 therebetween. These attraction members 15 on the central side hold a central portion of the upper wafer W1 during the separation processing.

The other one of the attraction members 15 is provided on the negative Y-axis side of the support member 13 (at a position adjacent to the protruding plate 132 on the negative Y-axis side). This attraction member 15 on the negative Y-axis side holds a negative Y-axis side of the upper wafer W1 during the separation processing.

The delivery holder 17 of the first holder 10 is provided on the base member 11, and serves to attract the non-bonding surface W1n of the separated upper wafer W1 held by the upper attraction device 14, thereby holding the upper wafer W1. The delivery holder 17 includes a base 171, multiple attraction pads 172, multiple contact pads 173, and a base elevating mechanism 174 (FIG. 4 shows one attraction pad 172 and one contact pad 173 as representatives).

The base 171 is formed to have a cylindrical shape that extends vertically and passes through a through hole (not shown) of the base member 11. The base 171 supports the multiple attraction pads 172 and the multiple contact pads 173 on a bottom end surface thereof. The base 171 is connected to the base elevating mechanism 174 and vertically moved up and down by the base elevating mechanism 174. When lowered, the base 171 passes through the through hole 133 of the support member 13.

The multiple attraction pads 172 are made of a rubber material or the like, and may have a bellows shape, for example, which allows it to follow the displacement of the upper wafer W1 in the vertical and horizontal directions. The multiple attraction pads 172 are connected via a suction path 175 to a suction device 176, such as a vacuum pump. The delivery holder 17 applies an attraction pressure (negative pressure) to the attraction pads 172 from the suction device 176 via the suction path 175 and the base 171, thereby attracting the non-bonding surface W1n of the upper wafer W1.

The multiple contact pads 173 are made of a resin material in a hemispherical shape or the like, and are brought into contact with the non-bonding surface W1n of the upper wafer W1 attracted by the respective attraction pads 172. A protrusion amount of the multiple contact pads 173 from the base 171 can be adjusted by a non-illustrated adjusting mechanism, thereby assisting in the separation of the upper wafer W1 from the delivery holder 17.

The base elevating mechanism 174 moves the base 171 up and down to displace the multiple attraction pads 172 and the multiple contact pads 173 in the vertical direction. By way of example, the base elevating mechanism 174 raises and lowers the attraction pads 172 and the contact pads 173 between a standby position, a hold exchange position where the separated upper wafer W1 held by the upper attraction device 14 is attracted, and a delivery position where the upper wafer W1 is handed over to the second transfer device 6.

Further, the second holder 20 of the separation apparatus 7 is disposed vertically below the first holder 10, and holds the lower wafer W2 by attracting the non-bonding surface W2n of the lower wafer W2 of the combined wafer T. The second holder 20 includes a disk-shaped lower chuck 21, a support column 22 supporting the lower chuck 21, and a rotating/elevating mechanism 23 configured to rotate the support column 22 and move it up and down.

The lower chuck 21 is made of a metal material such as aluminum, and has a circular attraction surface 21s on a top surface thereof. The attraction surface 21s is formed to have substantially the same diameter as the lower wafer W2. The attraction surface 21s is composed of a porous contact member 211 and is flat without grooves or holes. With this configuration, the lower chuck 21 is capable of attracting the lower wafer W2 in the entire surface of the attraction surface 21s. The contact member 211 is desirably formed of a resin material such as, but not limited to, polychlorotrifluoroethylene (PCTFE).

A suction space 212 communicating with the contact member 211 is formed inside the lower chuck 21. A suction pipe 213 communicating with the suction space 212 is connected to the exterior of the lower chuck 21. A suction path 214, which is provided with a suction device 215 such as a vacuum pump, is connected to the suction pipe 213. The second holder 20 generates an attracting pressure in the attraction surface 21s from the suction device 215 via the suction path 214, the suction pipe 213, and the suction space 212, thereby attracting the non-bonding surface W2n of the lower wafer W2. When placing the combined wafer T on the second holder 20, the position of the combined wafer T is adjusted so that the center of the combined wafer T (lower wafer W2) and the center of the attraction surface 21s of the lower wafer W2 are aligned with each other.

The rotating/elevating mechanism 23 incorporates a driving source for rotating the support column 22, a driving source for moving the support column 22 up and down, and a transmission mechanism for transmitting the driving force of each driving source (all of these are not shown). The rotating/elevating mechanism 23 rotates the lower chuck 21 around a vertical axis, and moves the lower chuck 21 up and down. Furthermore, the second holder 20 includes multiple elevating pins (not shown) for moving the combined wafer T or the separated lower wafer W2 relative to the attraction surface 21s.

The separation guide 30 of the separation apparatus 7 is disposed at the side of the first holder 10 and the second holder 20, and forms the separation start portion where the separation of the upper wafer W1 and the lower wafer W2 of the combined wafer T begins. The separation guide 30 includes a blade 31, a blade sliding mechanism 32, and a blade elevating mechanism 33.

The blade 31 is a separation member having a cutting edge that forms an acute angle toward the negative Y-axis direction. The blade sliding mechanism 32 includes a movable body 321 supporting the blade 31, and a fixed body 322 supporting the movable body 321 slidably. The movable body 321 supports the blade 31 so that the blade 31 protrudes horizontally, and is moved forward and backward in the Y-axis direction relative to the fixed body 322 by being driven by a non-illustrated driving source. That is, the direction of the forward and backward movement of the separating member in the present specification is the Y-axis direction in FIG. 4 and FIG. 5.

The blade elevating mechanism 33 is fixed to an end of the base member 11 on the positive Y-axis side, for example, and moves the blade sliding mechanism 32 vertically. This configuration allows the height position of the blade 31 to be adjusted and the blade 31 to face a position between the upper wafer W1 and the lower wafer W2.

After adjusting the height position of the blade 31 by using the blade elevating mechanism 33, the separation guide 30 advances the blade 31 in the negative Y-axis direction, using the blade sliding mechanism 32. As the blade 31 advances, the cutting edge of the blade 31 enters a bonding portion between the upper wafer W1 and the lower wafer W2 on a side surface of the combined wafer T, forming the separation start portion where the separation between the upper wafer W1 and the lower wafer W2 begins. The separation start portion is a portion where the bonding surface W1j of the upper wafer W1 is first separated from the bonding surface W2j of the lower wafer W2, creating a gap therebetween.

While attracting and holding the upper wafer W1 of the combined wafer T from above by using the first holder 10, the separation apparatus 7 attracts and holds the lower wafer W2 side of the combined wafer T from below by using the second holder 20 and forms the separation start portion by the separation guide 30. The separation apparatus 7 then raises the first holder 10 from the separation start portion (positive Y-axis side) to enlarge the gap between the upper wafer W1 and the lower wafer W2 to the opposite side (negative Y-axis side). As a result, the upper wafer W1 held by the first holder 10 is separated from the lower wafer W2.

Here, in a conventional separation apparatus, the separation of the upper wafer W1 and the lower wafer W2 takes time, and the upper wafer W1 may be damaged (cracked) when a local stress is applied to the upper wafer W1. To solve this problem, the separation apparatus 7 of the present disclosure is equipped with a gas ejector 40 configured to eject a gas between the upper wafer W1 and the lower wafer W2 to facilitate the separation of the upper wafer W1 and the lower wafer W2.

The gas ejector 40 includes a nozzle assembly 41 configured to eject a gas toward the combined wafer T, and a gas supply 42 that supplies the gas to the nozzle assembly 41. In the present exemplary embodiment, the gas ejected by the gas ejector 40 is air, but is not limited thereby and may be an inert gas such as an argon (Ar) gas or a nitrogen (N₂) gas.

The nozzle assembly 41 is positioned at the side of the combined substrate T held by the second holder 20 and adjacent to the separation guide 30 on the positive Y-axis side, and ejects the air from the positive Y-axis side. With this configuration, the nozzle assembly 41 ejects the air to the separation start portion formed by the blade 31 of the separation guide 30, thus easily guiding the air to be introduced between the upper wafer W1 and the lower wafer W2.

By way of example, the nozzle assembly 41 includes a nozzle 411, a pipe 412 that supplies the air to the nozzle 411, and a reciprocating device 413 that reciprocates the nozzle 411 and the pipe 412 vertically.

By being connected to an upper end of the pipe 412, the nozzle 411 is supported at a height position where it can face outer peripheries of the upper wafer W1 and the lower wafer W2 of the combined wafer T. The nozzle 411 has a base 411a, which is a connection portion with the pipe 412, and a protruding portion 411b protruding from the base 411a toward the negative Y-axis side with a narrowing tip. This protruding portion 411b has, in its end surface, an ejection opening 411c for the gas. For example, the ejection opening 411c is formed in a rectangular shape with a wider width in the horizontal direction and a narrower width in the vertical direction, and ejects the air horizontally. A flow path (not shown) for the air is provided inside the base 411a and the protruding portion 411b to communicate with the ejection opening 411c. It is desirable that this flow path is formed so that its cross sectional area decreases toward the ejection opening 411c. This allows the nozzle 411 to eject the air forcefully from the ejection opening 411c.

When viewing the combined wafer T and the nozzle assembly 41 from above (see FIG. 5), the air ejection direction from the nozzle 411 is set toward a position opposite to the separation start portion (a position on the negative Y-axis side), with the center of the combined wafer T therebetween. Along this air ejection direction, the gas ejector 40 can diffuse a large amount of air to a position where the upper wafer W1 and lower wafer W2 continue to be bonded during the separation thereof. Here, the air may be ejected from the ejection opening 411c of the nozzle 411 in a wide angle. The air ejection direction is a direction in which the air flows most easily based on the direction of the nozzle 411 and the shape of the ejection opening 411c. In FIG. 5, the air ejection direction refers to a direction extending from the axial line of the protruding portion 411b protruding from the base 411a.

The pipe 412 is formed of a rigid material, supports the nozzle 411, and supplies the air to the nozzle 411. While the pipe 412 is illustrated in FIG. 4 as being extended parallel to the vertical direction, the shape of the pipe 412 is not particularly limited, and the pipe 412 may have an appropriate shape depending on the layout of various configurations. A gas supply path 421 of the gas supply 42 is connected to a connector portion at a lower end of the pipe 412.

The reciprocating device 413 is a mechanical device that fixes and holds the pipe 412 and raises and lowers the pipe 412 and the nozzle 411 in the vertical direction (in other words, in a direction parallel to the thickness direction of the combined substrate T). The reciprocating device 413 performs a reciprocating motion that repeatedly raises and lowers the pipe 412 and the nozzle 411. For example, the reciprocating device 413 has therein a driving source and a transmission mechanism for transmitting a driving power of the driving source to the pipe 412 (both not shown). Further, the reciprocating device 413 is connected to the control device 8 in a communicative manner, and its operation is controlled by the control device 8. Under the control of the control device 8, the reciprocating device 413 reciprocates the nozzle 411 vertically when the nozzle 411 ejects the air.

Meanwhile, the gas supply 42 has the gas supply path 421 connected to the pipe 412, and this gas supply path 421 is equipped with a pump 422 and a flow adjuster 423. The gas supply path 421 is composed of multiple pipes and supplies the air to the pipe 412. In addition to the pump 422 and the flow adjuster 423, the gas supply path 421 may be further provided with various types of components (a valve, a filter, a temperature control mechanism, etc.).

The pump 422 is disposed upstream of the gas supply path 421 and force-feeds the air to the gas supply path 421. The type of the pump 422 is not particularly limited, and a blower, a compressor, or the like may be used, for example. The pump 422 is connected to the control device 8 in a communicative manner, and the timing of supplying the air is controlled by the control device 8.

The flow adjuster 423 is, for example, a mass flow controller, and is communicatively connected to the control device 8. The flow adjuster 423 controls the amount of the air ejected from the nozzle assembly 41 by adjusting the flow rate of the air flowing through the gas supply path 421 under the control of the control device 8.

Furthermore, the separation apparatus 7 may be equipped with one or more displacement meters 50 configured to detect the position of the upper wafer W1 during the separation of the combined wafer T. The displacement meter 50 is supported by the base member 11, for example, and positioned to face the outer periphery of the combined wafer T (upper wafer W1) held by the second holder 20. In particular, by providing multiple displacement meters 50 along the circumferential direction of the upper wafer W1 and using their detection results, the separation apparatus 7 is capable of monitoring a separation status such as the progress of the separation of the upper wafer W1.

### Separation Method

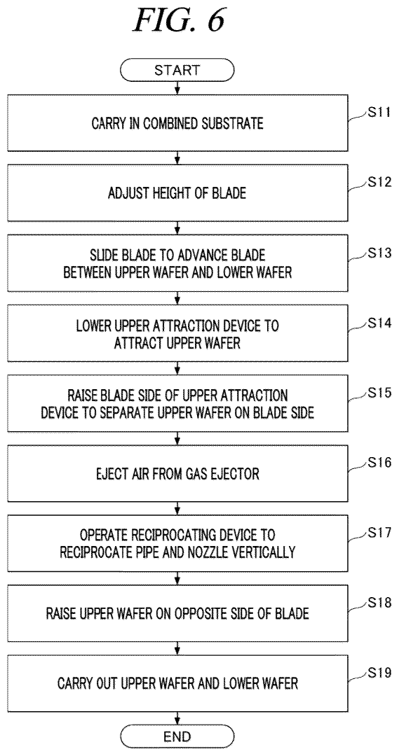

The separation system 100 and the separation apparatus 7 according to the first exemplary embodiment are basically configured as described above. Hereinafter, a separation processing (separation method) performed by them will be explained with reference to FIG. 6 to FIG. 8C.

When separating the combined wafer T in the separation apparatus 7, the control device 8 sequentially performs processes S11 to S19 shown in FIG. 6, for example.

To elaborate, the control device 8 first performs the carry-in processing of carrying the combined wafer T into the separation apparatus 7 (process S11). In this carry-in processing, the control device 8 controls the second transfer device 6 to transfer the combined wafer T from the first delivery section 25 (see FIG. 1) of the delivery station 2 to the separation apparatus 7 and carry the combined wafer T into the processing vessel 7c. Then, the control device 8 raises the multiple elevating pins of the second holder 20 located at the receiving position to receive the combined wafer T from the second transfer device 6, and then lowers the elevating pins to place the combined wafer T on the attraction surface 21s.

At this time, the combined wafer T is placed so that its center substantially coincides with the center of the attraction surface 21s of the second holder 20 and the center of the support member 13 (circular plate 131) of the first holder 10. Furthermore, the control device 8 operates the suction device 215 of the second holder 20 to generate the attracting pressure in the lower chuck 21, thereby attracting the non-bonding surface W2n of the lower wafer W2 to the attraction surface 21s.

Next, the control device 8 performs a processing of adjusting the height of the blade 31 (process S12). By way of example, the control device 8 operates the rotating/elevating mechanism 23 to raise the lower chuck 21 of the second holder 20 from the receiving position for the combined wafer T to a separation position, and also operates the blade elevating mechanism 33 to lower the blade 31 vertically downwards. At this time, the control device 8 may detect the height position of the combined wafer T by the displacement meter 50 and adjust the height position of the blade 31 by using this detection result. This allows the blade 31 to be precisely positioned so that it is horizontally aligned with the bonding portion between the upper wafer W1 and the lower wafer W2 of the combined wafer T.

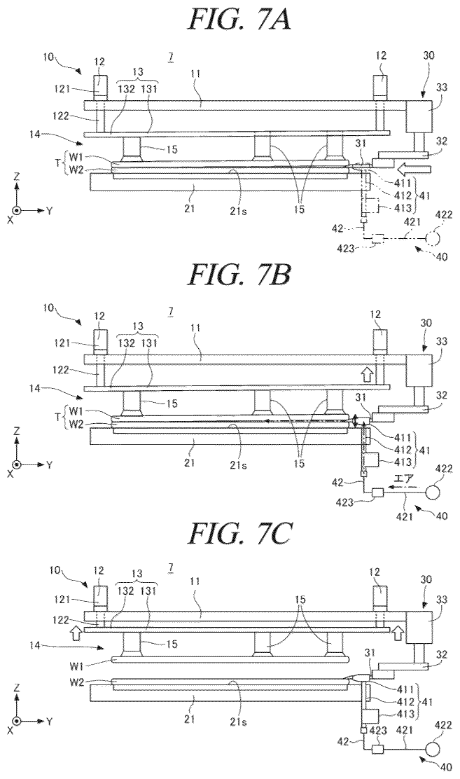

Thereafter, the control device 8 performs a processing of sliding the blade 31 in the negative Y-axis direction by controlling the blade sliding mechanism 32 of the separation guide 30 (process S13). By this sliding processing, the blade 31 is advanced into the bonding portion between the upper wafer W1 and the lower wafer W2 of the combined wafer T, forming the separation start portion, which is serve as a separation trigger, on the positive Y-axis side of the combined wafer T (see FIG. 7A). That is, at this separation start portion, the bonding surface W1j of the upper wafer W1 on the positive Y-axis side is separated from the bonding surface W2j of the lower wafer W2 by the blade 31.

Furthermore, in parallel with the sliding processing of the process S13, the control device 8 performs a processing of attracting the upper wafer W1 with the respective attraction members 15 by lowering the support members 13 and the upper attraction device 14 using the elevating mechanisms 12 of the first holder 10, (process S14: see FIG. 7A as well). As a result, the first holder 10 holds the upper wafer W1. The control device 8 then proceeds to an operation of separating the upper wafer W1 of the combined wafer T.

Specifically, the control device 8 first raises the upper attraction device 14 on the blade 31 side (positive Y-axis side) to separate (detach) the upper wafer W1 on the blade 31 side from the lower wafer W2 (process S15). That is, the control device 8 raises, between the pair of elevating mechanisms 12, the shaft 122 of the elevating mechanisms 12 on the positive Y-axis side, and raises the protruding plate 132 on the positive Y-axis side (see FIG. 7B). As a result, the respective attraction members 15 at the separation start portion where the blade 31 has been inserted are lifted vertically upwards, causing the upper wafer W1 at the separation start portion to start to be separated from the lower wafer W2. At this time, a counterclockwise moment as shown in FIG. 3 is generated at the separation start portion of the upper wafer W1, and each attraction member 15 on the positive Y-axis side pulls the upper wafer W1 so that it is lifted up from the outer edge thereof.

Furthermore, during a period in which the upper wafer W1 on the blade 31 side is being pulled up by the first holder 10, the control device 8 performs a processing of ejecting the air from the gas ejector 40 between the upper wafer W1 and the lower wafer W2 (process S16). The timing at which the gas ejector 40 ejects the air from the nozzle 411 is not limited to a timing when the upper wafer W1 is being lifted up. By way of example, the control device 8 may start the ejection of the air from the gas ejector 40 immediately after the separation start portion is formed by the sliding movement of the blade 31 or before the separation start portion is formed.

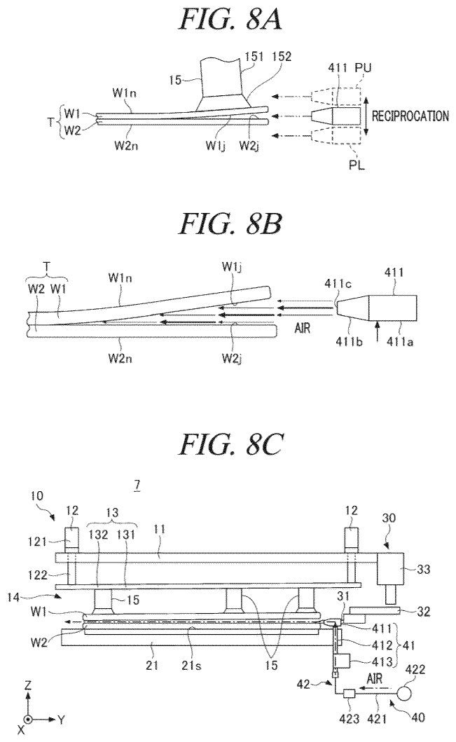

Furthermore, after starting the ejection of the air from the gas ejector 40, the control device 8 operates the reciprocating device 413 to vertically reciprocate (move up and down) the pipe 412 and the nozzle 411 (process S17). For example, as shown in FIG. 8A, the nozzle 411 is repeatedly moved between a first position PU above the non-bonding surface W1n of the separated upper wafer W1 and a second position PL below the non-bonding surface W2n of the lower wafer W2 by the reciprocating device 413.

As the nozzle 411 is reciprocated, as shown in FIG. 8B, the air ejected from the ejection opening 411c into the combined wafer T exhibits varying intensity both in the vertical direction and over time. In FIG. 8B, the intensity of the air is represented by the thickness of arrows, with thicker arrows indicating stronger airflow (with a higher flow rate) and thinner arrows indicating weaker airflow (with a lower flow rate).

That is, the gas ejector 40 is capable of ejecting the air to various locations on the combined wafer T, as compared to a case where the nozzle 411 constantly ejects the air without changing its ejection position. This allows the air to be more smoothly introduced into the narrow gap between the upper wafer W1 and the lower wafer W2, where the separation is progressing, thereby enlarging this gap rapidly. Therefore, as shown in FIG. 8C, the gas ejector 40 can separate the upper wafer W1 and the lower wafer W2 in a short time by ejecting the air.

Referring back to FIG. 6, when the elevating mechanism 12 on the positive Y-axis side has risen to a certain extent, the control device 8 starts raising the elevating mechanism 12 on the negative Y-axis side, thereby performing a processing of raising the upper wafer W1 on the opposite side of the blade 31 (process S18). At this stage, due to the previous ejection of the air from the gas ejector 40, the upper wafer W1 is completely separated from the lower wafer W2, as shown in FIG. 7C. Therefore, the first holder 10 can raise the upper wafer W1 and support it horizontally at the hold exchange position, suppressing the damage to the upper wafer W1.

Thereafter, the control device 8 proceeds to the carry-out processing of carrying the separated upper and lower wafers W1 and W2 from the separation apparatus 7 (process S19). In the carry-out processing, the control device 8 first returns the blade 31 to its initial position and lowers the lower chuck 21. The control device 8 then releases the attraction of the lower wafer W2 by the lower chuck 21 and raises the elevating pins to lift the lower wafer W2 from the attraction surface 21s. The control device 8 then controls the second transfer device 6 to move to a space below the lower wafer W2, and as the elevating pins are lowered, the lower wafer W2 is handed over to the second transfer device 6 and carried out from the separation apparatus 7. Furthermore, the control device 8 holds the upper wafer W1, which is held by the attraction members 15 of the upper attraction device 14 at the hold exchange position, with the delivery holder 17. Then, the control device 8 controls the second transfer device 6, which has advanced to a space vertically above the attraction pads 172 of the delivery holder 17, to attract and hold the non-bonding surface W1n of the upper wafer W1 and carry out the upper wafer W1 from the separation apparatus 7.

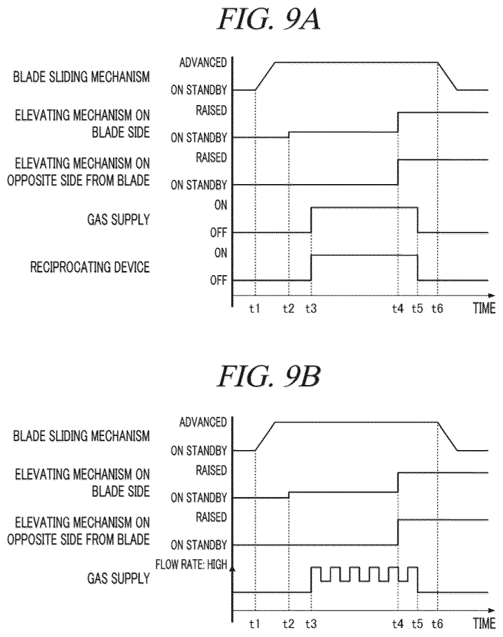

The operations of the individual components in the separation method of the separation apparatus 7 described above will be explained with reference to a timing chart shown in FIG. 9A. At time t1 after the start of the separation method, the control device 8 operates the blade sliding mechanism 32 to advance the blade 31 horizontally (in the negative Y-axis direction). As a result, the blade 31 is moved from the standby position to the position between the upper wafer W1 and the lower wafer W2, forming the separation start portion.

At time t2 after the separation start portion is formed, the control device 8 operates the elevating mechanism 12 on the blade 31 side (positive Y-axis side) to slightly raise the respective attraction members 15 on the positive Y-axis side. As a result, the separation of the upper wafer W1 and the lower wafer W2 from the separation start portion progresses.

At time t3 after the respective attraction members on the negative Y-axis side are raised, the control device 8 starts (turns on) the supply of the air by the gas supply 42 (pump 422) to eject the air from the nozzle 411 to the position between the upper wafer W1 and the lower wafer W2. Also, at the time t3, the control device 8 operates the reciprocating device 413 to reciprocate the nozzle 411 along the vertical direction. Here, the ejection of the air from the nozzle 411 and/or the reciprocation of the nozzle 411 may be performed before the time t3 (for example, at the same time as the time t2, or between the time t1 and the time t2). Due to the ejection of the air from the gas ejector 40, the separation between the upper wafer W1 and the lower wafer W2 across their entire surfaces is completed after a certain amount of time has elapsed since time t3.

At time t4 after the separation is completed, the control device 8 operates all the elevating mechanisms 12, including the elevating mechanism 12 on the opposite side (negative Y-axis side), to raise all the attraction members 15. This allows the upper wafer W1, which has been separated from the lower wafer W2, to be raised smoothly.

At time t5, the control device 8 stops the ejection of the air from the nozzle 411 and the reciprocation of the nozzle 411. Here, the ejection of the air from the nozzle 411 and the reciprocation of the nozzle 411 may be stopped at the same time as or before time t4. The control device 8 then proceeds to the carry-out processing of the upper wafer W1 and the lower wafer W2, and at time t6, operates the blade sliding mechanism 32 to retreat the blade 31.

As described above, the separation apparatus 7, the separation system 100, and the separation method according to the first exemplary embodiment include the gas ejector 40 configured to eject the gas between the upper wafer W1 and the lower wafer W2, and besides, the gas ejector 40 varies the ejection position as an ejection state after ejecting the gas. The air whose ejection state has been changed is introduced between the upper wafer W1 and the lower wafer W2, thereby allowing the two substrates (the upper wafer W1 and the lower wafer W2) to be efficiently and stably separated. In particular, the gas ejector 40 varies the ejection position of the air as the ejection state in parallel with the thickness direction of the combined wafer T. This causes the intensity of the gas to vary in the vertical direction, further facilitating the separation of the upper wafer W1 and the lower wafer W2. Therefore, the separation apparatus 7, the separation system 100, and the separation method can separate the upper wafer W1 and the lower wafer W2 in a short time while minimizing the damage to the upper wafer W1, thereby improving the overall yield of the separation processing.

Furthermore, the separation apparatus 7, the separation system 100, and the separation method of the present disclosure are not limited to the above-described exemplary embodiment, and may take various modification examples. By way of example, although the gas ejector 40 is configured to reciprocate the entire nozzle 411 in the vertical direction, the exemplary embodiment is not limited thereto, and there may be adopted a configuration in which the inclination of the nozzle 411 with respect to the vertical direction is varied to change the ejection direction of the air. For example, the gas ejector 40 may easily change the ejection direction of the air by moving the protruding portion 411b up and down about the connection portion between the base 411a and the pipe 412.

In addition, as shown in FIG. 9B, the separation apparatus 7 and the separation method according to a modification example are different from the above-described exemplary embodiment in that the ejection amount of the gas is varied as the ejection state instead of varying the ejection position. That is, the separation apparatus 7 does not include the reciprocating device 413, and instead performs a control to increase or decrease the ejection amount of the air using the flow adjuster 423. Apart from the configuration for adjusting the ejection amount of the air, this modification example is the same as the first exemplary embodiment, so a detailed description thereof will be omitted.

For example, at time t3 in the separation process, the control device 8 controls the flow adjuster 423 to alternate between a first ejection mode in which the air is ejected strongly and a second ejection mode in which the air is ejected weakly. This causes the air with the varying intensity over time to be introduced between the upper wafer W1 and the lower wafer W2 from the nozzle 411. Therefore, in this modification example, the gap between the upper wafer W1 and the lower wafer W2 can be enlarged rapidly, the same as in the first exemplary embodiment, which enables efficient and stable separation of the upper wafer W1 and the lower wafer W2. Here, in the second ejection mode, the ejection of the air may be reduced to zero (stopped).

Furthermore, in this modification example as well, the timing of starting the ejection of the gas is not limited to that shown in FIG. 9B. By way of example, it may be simultaneous with time t2 when the elevating mechanism 12 on the negative Y-axis side is raised, or it may be between time t1 when the separation start portion is formed and time t2. Furthermore, the separation apparatus 7 and the separation method according to this modification example may include the reciprocating device 413. That is, the separation apparatus 7 may be configured to adjust the ejection amount of the gas by using the flow adjuster 423 while varying the ejection position of the nozzle 411 by using the reciprocating device 413.

### Second Exemplary Embodiment

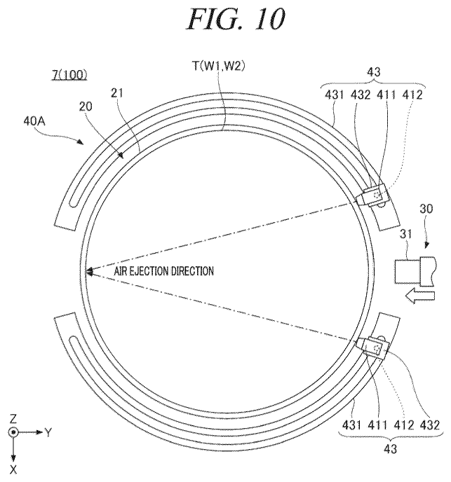

As illustrated in FIG. 10, a separation apparatus 7 (separation system 100) and a separation method according to a second exemplary embodiment is different from those of the first exemplary embodiment in that a gas ejector 40A configured to slide the nozzle 411 horizontally is used instead of the gas ejector 40. To elaborate, the gas ejector 40A is equipped with, as a nozzle assembly 43, a guide rail 431 and a horizontal moving device 432 instead of the reciprocating device 413, in addition to a nozzle 411 and a pipe 412. Further, the gas ejector 40A also includes this nozzle assembly 43 at each of the positive and negative X-axis sides, with the lower chuck 21 therebetween. That is, the gas ejector 40A is configured to eject a gas from each of a pair of nozzle assemblies 43 in the X-axis direction, and to slide a pair of nozzles 411 in the Y-axis direction.

As an example, the guide rail 431 is provided radially outside the lower chuck 21 of the second holder 20, spanning from a position adjacent to the blade 31 in the X-axis direction on the negative Y-axis side to a position opposite to the blade 31. This guide rail 431 extends in an arc shape to maintain a constant distance between the nozzle 411 and the outer edge of the combined wafer T held by the lower chuck 21. The arrangement range of the guide rail 431 is not limited to the illustrated example, and may be only the positive Y-axis side.

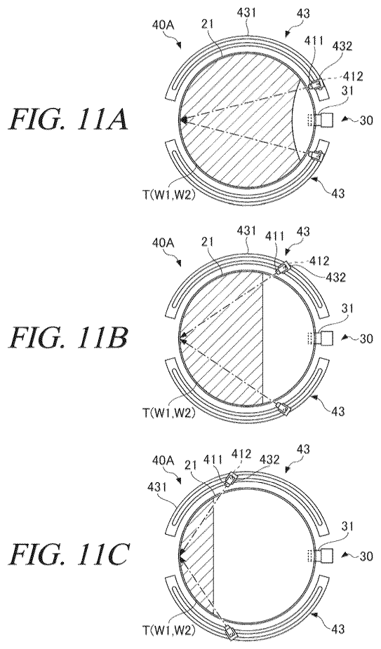

The horizontal moving device 432 incorporates a driving source and a transmission mechanism (not shown), and is configured to move on the guide rail 431 while supporting the pipe 412. The horizontal moving device 432 is communicatively connected to the control device 8, and its operation is controlled by the control device 8. By way of example, while ejecting the air from the nozzle 411, the horizontal moving device 432 moves the nozzle 411 from a start position on the positive Y-axis side to a sliding completion position on the negative Y-axis side. Furthermore, the horizontal moving device 432 may also be configured to change the direction of the nozzle 411 (the direction of the air ejection) when the nozzle 411 slides, as illustrated in FIG. 11A to FIG. 11C. In this case, desirably, the nozzle 411 may be set so that the air is always ejected toward a position opposite to the separation start position with the center of the combined substrate T therebetween.

The separation apparatus 7 and the separation system 100 according to the second exemplary embodiment are basically configured as described above, and their operation (separation method) will be explained below with reference to FIG. 11A to FIG. 11C. In FIG. 11A to FIG. 11C, a portion of the combined wafer T where the upper wafer W1 and the lower wafer W2 are bonded is hatched for ease of explanation.

In the separation method according to the second exemplary embodiment, before the formation of the separation start portion by the blade 31, the nozzle 411 is moved to the start position on the guide rail 431 on the positive Y-axis side to be on standby. The control device 8 advances the blade 31 into the combined wafer T to form the separation start portion. Then, when the elevating mechanisms 12 on the positive Y-axis side begin to rise, the control device 8 controls the air gas supply 42 to supply the air to the nozzle assembly 43, allowing the air to be ejected from the nozzle 411. Further, the ejection of the air may be started at the same time as or before the elevating mechanisms 12 on the positive Y-axis side are raised.

After the ejection of the air by the gas ejector 40A is begun, the control device 8 operates the horizontal moving device 432 to move the ejection position of the nozzle 411 toward the negative Y-axis side. At this time, the control device 8 controls the ejection position of each nozzle 411 depending on the separation state between the upper wafer W1 and the lower wafer W2. By way of example, immediately after the formation of the separation start portion between the upper wafer W1 and the lower wafer W2, each nozzle 411 is positioned on the positive Y-axis side, as illustrated in FIG. 11A.

Then, as shown in FIG. 11B, the control device 8 moves each nozzle 411 in the negative Y-axis direction as the separation between the upper wafer W1 and the lower wafer W2 expands in the negative Y-axis direction. For example, the ejection position of each nozzle 411 may be adjusted by detecting the position of the upper wafer W1 using the displacement meter 50 and controlling the operation of the horizontal moving device 432 based on this detection result. Alternatively, the moving speed of the nozzle 411 may be set in advance through an experiment or the like, and the nozzle 411 may be moved according to this moving speed.

As depicted in FIG. 11C, upon the completion of the separation between the upper wafer W1 and the lower wafer W2, each nozzle 411 is moved toward the negative Y-axis side relative to the center of the combined wafer T. This allows the gas ejector 40A to smoothly separate the upper wafer W1 and the lower wafer W2. Furthermore, in this separation method, it is also permissible for the separation of the upper wafer W1 and the lower wafer W2 to be completed while each nozzle 411 is being moved.

As stated above, in the separation apparatus 7 and the separation method according to the second exemplary embodiment, by including the gas ejector 40A configured to horizontally vary the ejection position of the nozzle 411 after the ejection of the gas, it is possible to separate the upper wafer W1 and the lower wafer W2 rapidly. In particular, the gas ejector 40A horizontally moves the ejection position as the ejection state of the gas. This allows the air to be ejected closer to the separation point, further facilitating the separation. Therefore, even in the second exemplary embodiment, the separation of the upper wafer W1 and the lower wafer W2 can be performed efficiently and stably while suppressing the damage to the upper wafer W1, which results in the increase of the overall yield of the separation processing.

### Third Exemplary Embodiment

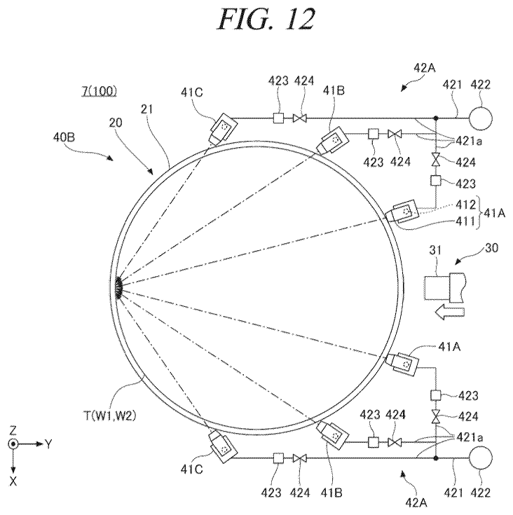

As illustrated in FIG. 12, a gas ejector 40B of a separation apparatus 7 (separation system 100) and a separation method according to a third exemplary embodiment is different from the gas ejectors 40 and 40A in that it has multiple nozzle assemblies 41 outside the combined wafer T held by the second holder 20. For example, three nozzle assemblies 41 are provided on the positive X-axis side relative to the blade 31, and other three nozzle assemblies 41 are provided on the positive X-axis side relative to the blade 31. Hereinafter, the pair of nozzle assemblies 41 located in the most positive Y-axis direction will be assigned a notation A; the pair of nozzle assemblies 41 adjacent to the nozzle assemblies 41A in the negative Y-axis direction, a notation B; and the pair of nozzle assemblies 41 adjacent to the nozzle assemblies 41B in the negative Y-axis direction, a notation C.

The height positions of nozzles 411 of the respective nozzle assemblies 41A to 41C are the same. The ejection directions of the air from the respective nozzle assemblies 41A to 41C are set to opposite positions (positions on the negative Y-axis side) from the separation start portion (the facing position of the blade 31), with the center of the combined wafer T therebetween. That is, the ejection directions of the air from the respective nozzle assemblies 41A to 41C are all different. By selectively switching among the multiple nozzle assemblies 41A to 41C to eject the air, the gas ejector 40A can change the ejection direction of the air as the ejection state of the air. Each of the nozzle assemblies 41A to 41C may be equipped with the reciprocating device 413 of the first exemplary embodiment to reciprocate the nozzle 411 vertically, or may not be equipped with the reciprocating device 413.

In the gas supply 42A, which supplies the air to each of the nozzle assemblies 41A to 41C, a gas supply path 421 is branched off into multiple branch paths 421a, and each branch path 421a is equipped with a flow adjuster 423 and an opening/closing valve 424. The gas supply 42 configured in this manner can select which pair of the nozzle assemblies 41A to 41C are to eject the air by switching the opening/closing operations of the respective opening/closing valves 424.

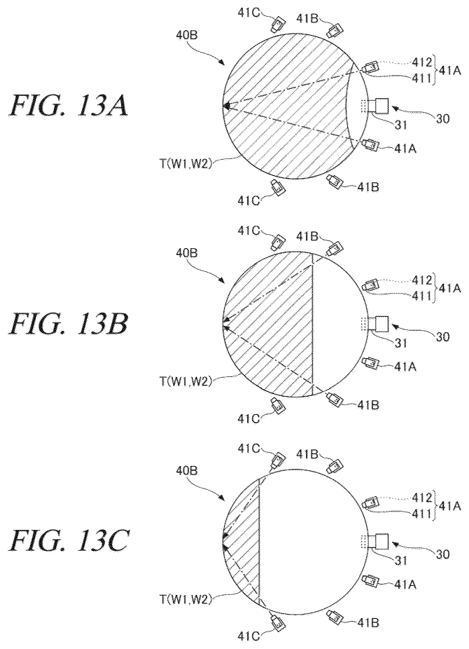

The separation apparatus 7 and the separation system 100 according to the third exemplary embodiment are basically configured as described above, and their operation (separation method) will be explained below with reference to FIG. 13A to FIG. 13C.

In the separation method according to the third exemplary embodiment, the control device 8 advances the blade 31 into the combined wafer T to form the separation start portion. When the elevating mechanisms 12 on the positive Y-axis side begin to rise, the gas ejector 40B begins to eject the air. In this case, the control device 8 controls the opening and closing operations of the respective valves 424 of the gas supply 42A to eject the air from the nozzle assemblies 41A located in the most positive Y-axis direction, as shown in FIG. 13A. The ejection of the air from the nozzle assemblies 41A may be started at the same time or before the elevating mechanisms 12 on the positive Y-axis side are raised.

After the ejection of the air by the gas ejector 40A is begun, the control device 8 switches the nozzle assemblies 41A to 41C to move the ejection position of the air toward the negative Y-axis side. Here, the control device 8 selects which pair of the nozzle assemblies 41A to 41C are to eject the air depending on the separation state between the upper wafer W1 and the lower wafer W2.

As illustrated in FIG. 13B, the control device 8 starts the ejection of the air from each nozzle assembly 41B when the separation between the upper wafer W1 and the lower wafer W2 expands in the negative Y-axis direction. Further, the ejection of the air from each nozzle assembly 41A may be stopped as shown in the illustrated example, or may be continued. By way of example, the timing at which each of the nozzle assemblies 41A to 41C starts to eject the air may be adjusted by detecting the position of the upper wafer W1 using the displacement meter 50 and controlling the operation of the horizontal moving device 432 based on this detection result. Alternatively, the control device 8 may set the ejection start timing in advance through an experiment or the like.

As depicted in FIG. 13C, when the separation between the upper wafer W1 and the lower wafer W2 is shifted in the positive Y-axis direction, the ejection of the air from each nozzle assembly 41C is begun. This allows the gas ejector 40B to eject the air from a position close to the separated portion, allowing the upper wafer W1 and the lower wafer W2 to be separated smoothly. Further, in this separation method, it is permissible for the separation of the upper wafer W1 and the lower wafer W2 to be completed while each nozzle 411 is being moved.

As described above, in the separation apparatus 7, the separation system 100, and the separation method according to the third exemplary embodiment, by providing the gas ejector 40B configured to switch between the multiple nozzle assemblies 41A to 41C after the ejection of the air, it is possible to rapidly separate the upper wafer W1 and the lower wafer W2. In particular, the gas ejector 40B changes the ejection position and the ejection direction as the ejection state of the gas. This allows for greater variations in the air being ejected. Therefore, in the third exemplary embodiment as well, the efficient separation of the upper wafer W1 and the lower wafer W2 can be carried out while suppressing the damage to the upper wafer W1, thereby improving the overall yield of the separation processing.

The separation apparatus 7, the separation system 100, and the separation method according to the exemplary embodiments of the present disclosure are illustrative in all aspects and are not anyway limiting. The above exemplary embodiments may be modified and improved in various forms without departing from the scope and the spirit of the appended claims. The matters described in the above-described exemplary embodiments may take on other configurations and may be combined unless they are contradictory.

This application claims priority to Japanese Patent Application No. 2023-073628, field on Apr. 27, 2023, which application is hereby incorporated by reference in their entirety.

### EXPLANATION OF CODES

7: Separation apparatus
10: First holder
20: Second holder
30: Separation guide
40: Gas ejector
100: Separation system
T: Combined substrate (combined wafer)
W1: First substrate (upper wafer)
W2: Second substrate (lower wafer)

1. A separation apparatus configured to separate a combined substrate, in which a first substrate and a second substrate are bonded, into the first substrate and the second substrate, the separation apparatus comprising:
a first holder configured to hold the first substrate of the combined substrate;
a second holder configured to hold the second substrate of the combined substrate;
a separation guide configured to be advanced between the first substrate and the second substrate of the combined substrate to form a separation start portion where separation begins; and
a gas ejector configured to eject a gas between the first substrate and the second substrate of the combined substrate,
wherein the gas ejector changes at least one of an ejection position, an ejection direction, or an ejection amount as an ejection state of the gas after the separation start portion is formed by the separation guide and the gas is ejected.

2. The separation apparatus of claim 1,
wherein the gas ejector is disposed at least at a position on a lateral side of the combined substrate held by the second holder and the gas ejector is adjacent to the separation guide when starting ejection of the gas.

3. The separation apparatus of claim 2,
wherein the gas ejector sets the ejection direction of the gas to an opposite position from the separation start portion, with a center of the combined substrate therebetween.

4. The separation apparatus of claim 1, further comprising:
a control circuitry configured to control the first holder, the second holder, the separation guide, and the gas ejector,
wherein the control circuitry is configured to change the ejection state of the gas from the gas ejector during a period in which the separation start portion is formed and the first substrate is separated from the second substrate while the first substrate is being held by the first holder.

5. The separation apparatus of claim 1,
wherein the gas ejector comprises:
a nozzle assembly having a nozzle configured to eject the gas toward the combined substrate; and
a gas supply configured to supply the gas to the nozzle, and
the nozzle assembly comprises a reciprocating device configured to reciprocate the nozzle in a direction parallel to a thickness direction of the combined substrate, and the nozzle assembly changes the ejection position as the ejection state of the gas.

6. The separation apparatus of claim 5,
wherein the reciprocating device reciprocates the nozzle between a first position above a non-bonding surface of the first substrate and a second position below a non-bonding surface of the second substrate.

7. The separation apparatus of claim 1,
wherein the gas ejector comprises:
a nozzle assembly having a nozzle configured to eject the gas toward the combined substrate; and
a gas supply configured to supply the gas to the nozzle, and
the nozzle assembly comprises a flow adjuster configured to adjust the ejection amount of the gas from the nozzle, and the nozzle assembly changes the ejection amount as the ejection state of the gas.

8. The separation apparatus of claim 1, wherein the gas ejector comprises:
a nozzle assembly having a nozzle configured to eject the gas toward the combined substrate; and
a gas supply configured to supply the gas to the nozzle, and
the nozzle assembly comprises, at a lateral side of an outer edge of the combined substrate, a horizontal moving device configured to move the nozzle in a horizontal direction, and the nozzle assembly changes the ejection position as the ejection state of the gas.

9. The separation apparatus of claim 8,
wherein the nozzle assembly moves the nozzle in an arc shape at the lateral side of the outer edge of the combined substrate to maintain a constant distance between the outer edge of the combined substrate and the nozzle.

10. The separation apparatus of claim 1,
wherein the gas ejector comprises:
multiple nozzle assemblies each configured to, at a lateral side of an outer edge of the combined substrate, eject the gas toward the combined substrate; and
a gas supply configured to supply the gas to the multiple nozzle assemblies, and
the ejection position as the ejection state of the gas is changed by selectively switching among the multiple nozzle assemblies to eject the gas.

11. The separation apparatus of claim 10,
wherein the multiple nozzle assemblies have different ejection directions of the gas, and
the gas ejector changes the ejection direction of the gas as the ejection state of the gas by selectively switching among the multiple nozzle assemblies to eject the gas.

12. A separation system, comprising:
a separation apparatus configured to separate a combined substrate, in which a first substrate and a second substrate are bonded, into the first substrate and the substrate; and
a substrate transfer device configured to carry the combined substrate into the separation apparatus and carry out each of the separated first substrate and the separated second substrate from the separation apparatus,
wherein the separation apparatus comprises:
a first holder configured to hold the first substrate of the combined substrate;
a second holder configured to hold the second substrate of the combined substrate;
a separation guide configured to be advanced between the first substrate and the second substrate of the combined substrate to form a separation start portion where separation begins; and
a gas ejector configured to eject a gas between the first substrate and the second substrate of the combined substrate, and
the gas ejector changes at least one of an ejection position, an ejection direction, or an ejection amount as an ejection state of the gas after the separation start portion is formed by the separation guide and the gas is ejected.

13. A separation method of separating a combined substrate, in which a first substrate and a second substrate are bonded, into the first substrate and the second substrate, the separation method comprising:
holding the first substrate of the combined substrate with a first holder;
holding the second substrate of the combined substrate with a second holder;
forming a separation start portion, where separation begins, by advancing a separation guide between the first substrate and the second substrate of the combined substrate; and
allowing the separation to progress by separating the first substrate from the second substrate, starting from the separation start portion,
wherein in the allowing of the separation to progress, a gas is ejected between the first substrate and the second substrate of the combined substrate from a gas ejector, and at least one of an ejection position, an ejection direction, or an ejection amount is changed as an ejection state of the gas.

14. The separation method of claim 13,
wherein the gas ejector is disposed at least at a position on a lateral side of the combined substrate held by the second holder and the gas ejector is adjacent to the separation guide when starting ejection of the gas.

15. The separation method of claim 14, further comprising:
setting, by the gas ejector, the ejection direction of the gas to an opposite position from the separation start portion, with a center of the combined substrate therebetween.

16. The separation method of claim 13,
wherein the gas ejector comprises:
a nozzle assembly having a nozzle and a reciprocating device; and
a gas supply, and
the separation method further comprises reciprocating, by the reciprocating device, the nozzle in a direction parallel to a thickness direction of the combined substrate, and changing the ejection position as the ejection state of the gas.

17. The separation method of claim 16,
wherein the reciprocating device reciprocates the nozzle between a first position above a non-bonding surface of the first substrate and a second position below a non-bonding surface of the second substrate.

18. The separation method of claim 13,
wherein the gas ejector comprises:
a nozzle assembly having a nozzle and a flow adjuster; and
a gas supply, and
the separation method further comprises adjusting, by the flow adjuster, the ejection amount of the gas from the nozzle, and changing the ejection amount as the ejection state of the gas.

19. The separation method of claim 13,
wherein the gas ejector comprises:
a nozzle assembly having a nozzle configured to eject the gas toward the combined substrate; and
a gas supply configured to supply the gas to the nozzle, and
the nozzle assembly comprises, at a lateral side of an outer edge of the combined substrate, a horizontal moving device, and
the separation method further comprises moving, by the horizontal moving device, the nozzle in a horizontal direction, and changing the ejection position as the ejection state of the gas.

20. The separation method of claim 19,
wherein the nozzle assembly moves the nozzle in an arc shape at the lateral side of the outer edge of the combined substrate to maintain a constant distance between the outer edge of the combined substrate and the nozzle.
